(19) United States
(12) Patent Application Publication
(10) Pub. No.: US 2009/0121322 A1
(43) Pub. Date: May 14, 2009

(54) Semiconductor chip and semiconductor device

(75) Inventor: Ken Ozawa, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/289,452

(22) Filed: Oct. 28, 2008

(30) Foreign Application Priority Data
Nov. 8, 2007 (JP) 2007-291045

(51) Int. Cl. H01L 23/58; H01L 21/44

(52) U.S. Cl. 257/620; 438/622; 257/E23.002; 257/E21.476

(57) ABSTRACT

A semiconductor chip comprises a semiconductor substrate, a multi-layer wiring structure on the semiconductor substrate, a seal ring structure on the semiconductor substrate, and a semiconductor element arranged in an inner region of said semiconductor chip and in a frame region of said semiconductor chip. The semiconductor element comprises a chip internal circuit, the inner region is enclosed by the seal ling structure, and the seal ring structure separates the frame region as being outside of the inner region.

### BACKGROUND

1. Field of the Invention

The present invention relates to a semiconductor chip and a semiconductor device, and more specifically, to a semiconductor chip having a multi-layer wiring structure and a seal ring, and a semiconductor device having the semiconductor chip mounted thereon.

2. Description of Related Art

A large-scale integrated circuit (LSI) such as a microprocessor or a memory known as a representative of semiconductor devices has become finer in size of each of its elements as higher levels of integration are achieved, so that correspondingly a size of a semiconductor region making up each of the elements has also become finer. Further, in order to reserve a high wiring density corresponding to a high integration density, it is not enough to form the wiring line only in a plane direction of a semiconductor substrate, so that multi-layer wiring technologies have been employed, by which the wiring lines are formed on a plurality of layers in a thickness direction of the semiconductor substrate. A multi-layer wiring structure including six to nine layers is realized in an example of a microprocessor, which is a representative of the LSIs.

In such the LSI that a multi-layer wiring structure is employed, a resistance value of the wiring lines has a large influence on characteristics such as an operating speed, so that the wiring line is desired to have a smaller resistance value. Conventionally, as a material of the wiring lines of semiconductor devices including LSIs, aluminum (Al) excellent in electrical characteristics, processability, and the like, or aluminum-based metal has been used generally. However, aluminum-based metal has a drawback of being low in electro-migration resistance, stress-migration resistance, and the like. Therefore, there is a recent tendency to replace aluminum-based metal with copper (Cu) or copper-based metal that has a smaller resistance value and is excellent in electro-migration resistance, stress-migration resistance, or the like.

However, when forming the wiring lines using copper-based metal, a copper-based compound, which has a low vapor pressure, is difficult to pattern into a desired shape utilizing dry etching technologies as compared to aluminum-based metal. Therefore, to form the wiring line using copper-based metal, a known single damascene wiring technology is employed, by which after forming beforehand a wiring trench in an interlayer insulating film formed on the semiconductor substrate and the copper-based metal film throughout a surface including this wiring trench, an unnecessary portion of the copper-based metal on the interlayer insulating film is removed by Chemical Mechanical Polishing (CMP) so as to provide as the wiring line a portion of the copper-based metal film left (buried) only in the wiring trench. Further, a dual damascene wiring technology, which is an extension of the single damascene wiring technology, is employed, by which a structure suited for fine-patterned multi-layer wiring is realized.

In the semiconductor device having the multi-layer wiring structure, a high-speed operation is affected by a signal delay due to, for example, an increase in inter-wiring line capacitance given by an interlayer insulating film present between a lower-layer wiring line and an upper-layer wiring line or an increase in inter-wiring line capacitance caused by a decrease in plane directional inter-wiring-line interval caused by an improvement in fine patterning. Therefore, there is a tendency to use a low-dielectric-constant film (so-called low-k insulation film) as the interlayer insulating film in order to reduce the capacitance due to the interlayer insulating film.

In manufacturing the LSI, after necessary circuit elements are integrated on the semiconductor substrate (wafer), the semiconductor substrate is separated into individual semiconductor chip by dicing. However, in this case, a dicing face of the semiconductor chip, that is, a sidewall of an interlayer insulating film is exposed, so that water, moisture, and the like (hereinafter referred to as “water and the like”) penetrates through the dicing face, thus deteriorating moisture resistance. Especially, the LSI employing such as a multi-layer wiring structure as described above has a larger number of interlayer insulating film layers and so tends more to suffer from such deterioration in moisture resistance. It, therefore, may lead to a drawback such as an increase in leakage current or in dielectric constant of an originally low-dielectric-constant film.

A structure of providing a seal ring in such a manner as to surround a circuit formation portion of a semiconductor chip in order to improve moisture resistance by preventing water and the like from penetrating through a dicing face is disclosed in Japanese Unexamined Patent Application Publication No. 2004-297022. Japanese Unexamined Patent Application Publication No. 2002-134506 discloses a structure of providing a first guard ring (seal ring) so as to surround a production-line chip and a second guard ring (seal ring) inside the first guard ring. It is possible to improve a quality and reliability by providing the first guard ring and the second guard ring to suppress a deformation of contact holes in the vicinity of a guard ring.

### SUMMARY

In recent years, high performance of a semiconductor chip has been highly demanded. Although it is possible to realize high performance by increasing the size of the semiconductor chip, there is a high demand of decreasing the size thereof. A technique of realizing the high performance without increasing the size of the semiconductor chip has been demanded.

A first exemplary aspect of an embodiment of the present invention is a semiconductor chip comprises a semiconductor substrate, a multi-layer wiring structure on the semiconductor substrate, a seal ring structure on the semiconductor substrate, and a semiconductor element arranged in an inner region of said semiconductor chip and in a frame region of said semiconductor chip. The semiconductor element comprises a chip internal circuit, the inner region is enclosed by the seal ling structure, and the seal ring structure separates the frame region as being outside of the inner region.

A second exemplary aspect of an embodiment of the present invention is a semiconductor device comprising a semiconductor substrate, and a semiconductor chip including a multi-layer wiring structure and a seal ring structure on the semiconductor substrate, wherein the semiconductor chip comprises a semiconductor element arranged in an inner region of the semiconductor chip a frame region of the semiconductor chip, the semiconductor element comprising a chip internal circuit component, the inner region being enclosed to be inside of the seal ring structure, and the frame region is separated as outside of the inner region by the seal ring structure.

A third exemplary aspect of an embodiment of the present invention is a method of fabricating a semiconductor chip, said method comprising forming a semiconductor element on a substrate, and forming a multi-layer wiring structure on the substrate, including a seal ring structure, wherein the seal ring structure separates the chip into an inner region enclosed by the seal ring structure and a frame region being outside the seal ring structure, and the semiconductor element comprises a chip internal circuit component and is located partially in the inner region and partially in the frame region.

According to the semiconductor chip of the present invention, it is possible to realize the high performance without increasing the size of the semiconductor chip since there is provided a semiconductor element which is operable as a chip internal circuit and has a high reliability not only in the inner region but in the frame region segmented outside of the inner region. That is, it is possible to provide the semiconductor chip which can realize the high performance without increasing the size of the semiconductor chip.

### BRIEF DESCRIPTION OF THE DRAWINGS

The above and other exemplary aspects, advantages and features will be more apparent from the following description of certain exemplary embodiments taken in conjunction with the accompanying drawings, in which:

FIGS. 1A and 1B show a schematic plan view of a semiconductor device according to a first embodiment;

FIG. 2 is a cross sectional view taken along the line II-II of FIG. 1B;

FIG. 3 is a partially-enlarged plan view of an outer peripheral part A1 of a semiconductor chip according to the first embodiment;

FIG. 4 is a cross sectional view taken along the line IV-IV of FIG. 3;

FIG. 5 is a cross sectional view taken along the line V-V of FIG. 3;

FIG. 6 is a cross sectional view taken along the line VI-VI of FIG. 3;

FIG. 7 is a partially-enlarged plan view of an outer peripheral part of a semiconductor chip according to a second embodiment;

FIG. 8 is a cross sectional view taken along the line VIII-VIII of FIG. 7;

FIG. 9 is a cross sectional view taken along the line IX-IX of FIG. 7; and

FIG. 10 is a cross sectional view taken along the line X-X of FIG. 7.

### DETAILED DESCRIPTION OF THE EXEMPLARY EMBODIMENTS

Hereinafter, one example of the embodiment to which the present invention is applied will be described. Needless to say, other exemplary embodiments which are not described in this specification may be within the scope of the present invention without departing from the spirit of the present invention.

### First Exemplary Embodiment

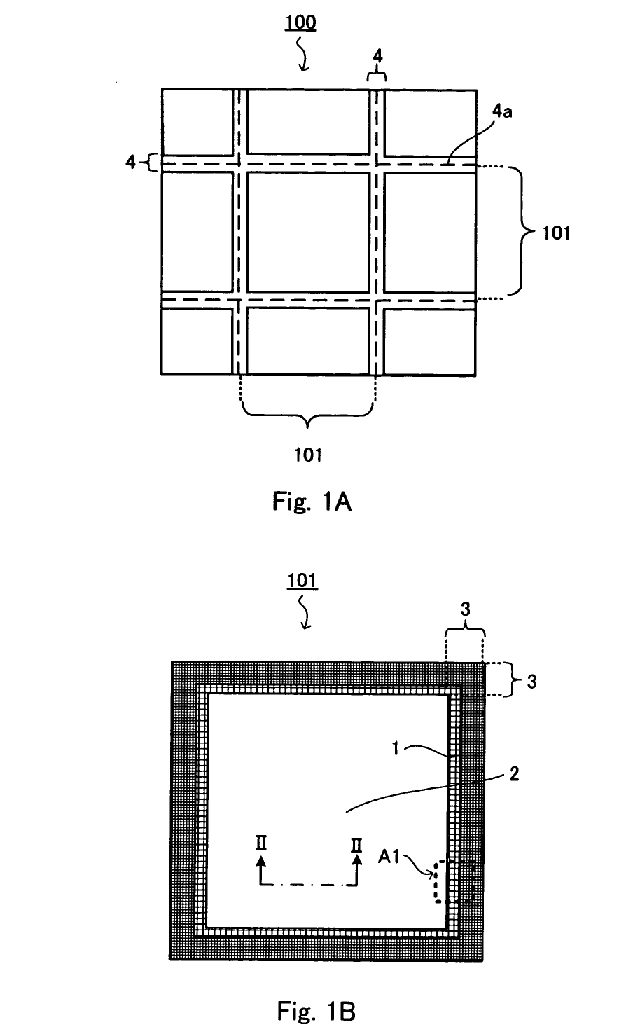

FIG. 1A is a top view showing a part of a semiconductor wafer 100 according to the first exemplary embodiment, and FIG. 1B is a top view of a semiconductor chip 101 taken out by cutting the semiconductor wafer 100 by dicing. As shown in FIG. 1A, a scribe line region 4 is formed in a lattice shape in the semiconductor wafer 100. The semiconductor chip 101 is taken out by cutting the semiconductor wafer 100 along the scribe line 4a.

As shown in FIG. 1B, in the semiconductor chip 101 according to the first exemplary embodiment, a seal ring 1 is provided in an outer peripheral part in a frame body shape. In this specification, the inner side of the seal ring 1 is called the inner region 2, and the region outside of the inner region 2 is called the frame region 3. The frame region 3 is the region where the seal ring 1 and a scribe line region 4 are formed. The seal ring 1 is typically formed in the inner side of the scribe line region 4 with having trench therebetween. In other words, the trench having substantially constant width is formed between the scribe line region 4 and the seal ring 1. The seal ring 1 prevents water or the like from being penetrated inside the semiconductor chip when the semiconductor wafer is cut by dicing and prevents the interlayer insulating film from being cracked due to the dicing.

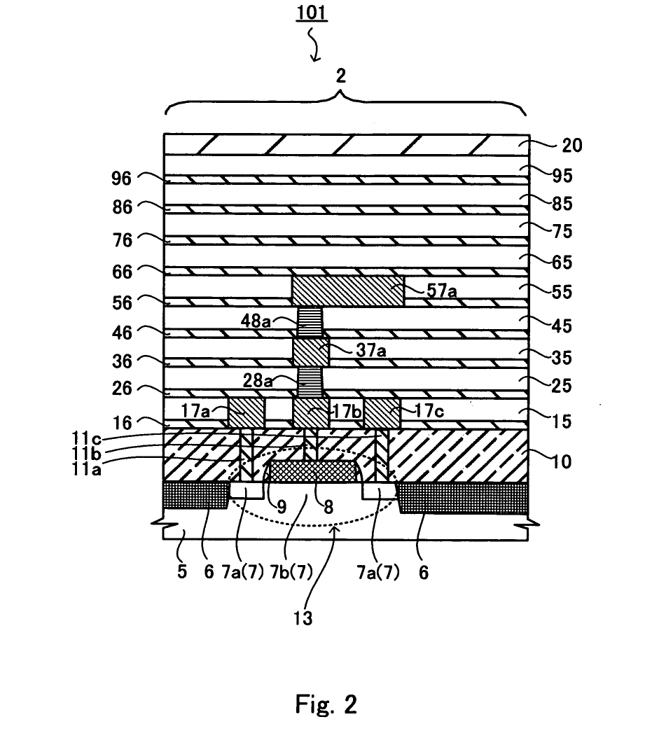

FIG. 2 shows a cross sectional view taken along the line II-II of FIG. 1B, or a cross sectional view of the inner region 2. As shown in FIG. 2, the semiconductor chip 101 according to the first exemplary embodiment includes a semiconductor substrate 5, a gate part 8, a side wall 9, an element protecting film 10, a contact 11, an N channel Metal Oxide Silicon (MOS)-type transistor (hereinafter simply referred to as “MOS transistor”) 13, interlayer insulating films having nine layers (first interlayer insulating film 15, second interlayer insulating film 25, third interlayer insulating film 35, fourth interlayer insulating film 45, fifth interlayer insulating film 55, sixth interlayer insulating film 65, seventh interlayer insulating film 75, eighth interlayer insulating film 85, and ninth interlayer insulating film 95), etching stoppers having nine layers (first etching stopper film 16, second etching stopper film 26, third etching stopper film 36, fourth etching stopper film 46, fifth etching stopper film 56, sixth etching stopper film 66, seventh etching stopper film 76, eighth etching stopper film 86, and ninth etching stopper film 96), and a passivation protecting film 20 and so on.

The semiconductor substrate 5 is formed by P-type silicon, for example. The semiconductor substrate 5 includes an element isolation region 6 formed by a Shallow Trench Isolation (STI) or the like and an active region 7 surrounded by the element isolation region 6. The active region 7 has a pair of N-type diffusion region 7a which becomes a source region or a drain region and an inversion layer forming region 7b arranged opposed to at least a part of the gate part 8.

The gate part 8 is formed in the upper layer of the inversion layer forming region 7b which is the region opposed to the pair of N-type diffusion region 7a. The gate part 8 is formed by the gate insulation film such as a silicon oxide film and a gate electrode formed on the gate insulation film. The gate electrode is formed by a silicide layer such as polycrystal Si (polysilicon), nickel silicide (NiSi), platinum silicide (PtSi), for example. The MOS transistor 13 which is the semiconductor element which is operable as the chip internal circuit and has a high reliability is formed by the above structure.

The element protecting film 10 is formed so as to cover the gate part 8. The element protecting film 10 is preferably formed so as to have a configuration of a single layer or stacked layers selected from a silicon oxide film (SiO), a silicon carbonate film (SiC), a silicon carbonitride film (SiCN), a silicon oxinitride film (SiON), and a silicon nitride film (SIN) More preferably, the element protecting film 10 is formed of the silicon oxide film. The element protecting film 10 includes a contact 11 (11a to 11c) penetrating from the surface to the pair of N-type diffusion region 7a and the gate part 8.

A contact hole for forming the contact 11 (11a to 11c) formed in the element protecting film 10 is formed by a known photolithography process or an etching process or the like. In the contact hole, a contact 11 (11a to 11c) is formed which includes a tungsten layer and a barrier metal (not shown) having configuration of stacked layers made up of a titanium film (Ti) having a film thickness of 5 to 15 nm and a titanium nitride film (TiN) having a film thickness of 10 to 20 nm, for example. The N-type diffusion region 7a and the first wiring layer 17a formed in the first interlayer insulating film 15 formed in the upper layer of the element protecting film 10 are electrically connected by the contact 11a. In the same way, the gate part 8 and the first wiring layer 17b are electrically connected by the contact 11b, and the N-type diffusion region 7a and the first wiring layer 17c are electrically connected by the contact 11c (see FIG. 2).

The etching stopper films having nine layers and the interlayer insulating films having nine layers are stacked in the upper layer of the element protecting film 10. More specifically, as shown in FIG. 2, the first interlayer insulating film 15, the second interlayer insulating film 25, the third interlayer insulating film 35, the fourth interlayer insulating film 45, the fifth interlayer insulating film 55, the sixth interlayer insulating film 65, the seventh interlayer insulating film 75, the eighth interlayer insulating film 85, and the ninth interlayer insulating film 95 are stacked in this order on the element protecting film 10. Then the etching stopper films are formed in the lower layer of each of the interlayer insulating films. To be more specific, the first etching stopper film 16 is formed in the lower layer of the first interlayer insulating film 15, the second etching stopper film 26 is formed in the lower layer of the second interlayer insulating film 25, the third etching stopper film 36 is formed in the lower layer of the third interlayer insulating film 35, the fourth etching stopper film 46 is formed in the lower layer of the fourth interlayer insulating film 45, the fifth etching stopper film 56 is formed in the lower layer of the fifth interlayer insulating film 55, the sixth etching stopper film 66 is formed in the lower layer of the sixth interlayer insulating film 65, the seventh etching stopper film 76 is formed in the lower layer of the seventh interlayer insulating film 75, the eight etching stopper film 86 is formed in the lower layer of the eighth interlayer insulating film 85, and the ninth etching stopper film 96 is formed in the lower layer of the ninth interlayer insulating film 95.

Each of the etching stopper films is formed of SiCN or silicon nitride film (SiN) having a film thickness of 10 to 50 nm, for example, and each of the interlayer insulating films is formed by a low-dielectric-constant film having a film thickness of 150 to 300 nm, for example. A trench (wiring trench) for providing the wiring line is formed in the first interlayer insulating film 15 and the first etching stopper film. In the trench, the first wiring layers 17a, 17b, and 17c are formed which include a copper layer (not shown) and a barrier metal (not shown) having configuration of stacked layers made up of a tantalum film (Ta) and a tantalum nitride film (TaN) having a film thickness of 10 to 30 nm, for example. A via hole (via wiring trench) is formed in the second interlayer insulating film 25. In this via hole, a first via wiring layer 28a which includes a copper layer and a barrier metal having configuration of stacked layers made up of a tantalum film and a tantalum nitride film having a film thickness of 10 to 30 nm is formed, for example. The first via wiring layer 28a is formed so as to be connected to the first wiring layer 17b which is one of the three first wiring layers.

In the same way, a trench for providing the wiring line is formed in the etching stopper film and the interlayer insulating film of an odd-number layer to form the wiring layer in the trench. The via hole for forming the via is formed in the etching stopper film and the interlayer insulating film of an even-number layer to form the via wiring layer in the via hole. In FIG. 2, a second wiring layer 37a is superimposed in a film-thickness direction with respect to the first via wiring layer 28a so as to be connected to the first via wiring layer 28a. Further, a second via wiring layer 48a formed in the fourth interlayer insulating film 45 is formed so as to be connected to the second wiring layer 37a, and a third wiring layer 57a formed in the fifth interlayer insulating film 55 is superimposed in the film-thickness direction so as to be connected to the second via 48a. The passivation film 20 is formed in the upper layer of the ninth interlayer insulating film 95. The passivation protecting film 20 is preferably SiO or SiON, for example.

The interlayer insulating film preferably employs low-dielectric-constant film as a main layer. It is possible to suppress the increase of the inter-wiring line capacitance by employing the low-dielectric-constant film. As the low-dielectric-constant film, SiLK (registered trademark of Dow Chemical Company) can be employed, for example. Note that the phrase “main layer of the interlayer insulating film” means the layer which occupies most of the film-thickness direction and plays a main role when the interlayer insulating film is formed by a plurality of stacked layers.

On the other hand, the element protecting film 10 is formed by material different from that of the main layer of the interlayer insulating film. The element protecting film 10 is formed by a film having high moisture resistance and realizing high reliability. As stated above, the element protecting film 10 is preferably a single layer or stacked layers selected from SiO, SiC, SiCN, SiON, and SiN.

The semiconductor chip 101 according to the first exemplary embodiment includes multi-layer wiring lines formed of the first wiring layers 17a, 17b, and 17c, the second wiring layer 37a, the third wiring layer 57a, the first via wiring layer 28a, and the second via wiring layer 48a, and the MOS transistor 13 which is the semiconductor element electrically connected to each other as described above.

Now, the characteristics of the exemplary embodiment will be described. In the first exemplary embodiment, the region arranging the semiconductor element which is operable as the chip internal circuit and has a high reliability is extended to the frame region 3 including the seal ring 1 in addition to the inner region 2. Hereinafter, the “semiconductor element which is operable as the chip internal circuit and has a high reliability” is simply referred to as “semiconductor element”. The semiconductor element for test, which is the element for checking characteristics and does not operate as the internal circuit, is referred to as “semiconductor element for test” in order to make a distinction. Note that, in the present invention, it does not exclude a case of providing the semiconductor element for test, but it is possible to provide a semiconductor element for checking operation in the frame region 3 or in the inner region 2 in addition to the “semiconductor element which is operable as the chip internal circuit and has a high reliability”.

The semiconductor element is needed to be arranged in the frame region 3 so as not to expose the sidewall of the semiconductor chip, that is, the dicing face in order to secure the reliability.

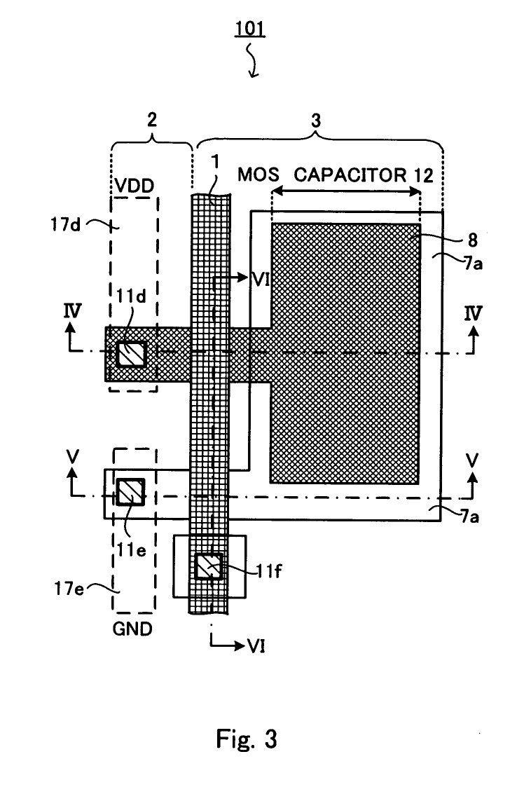

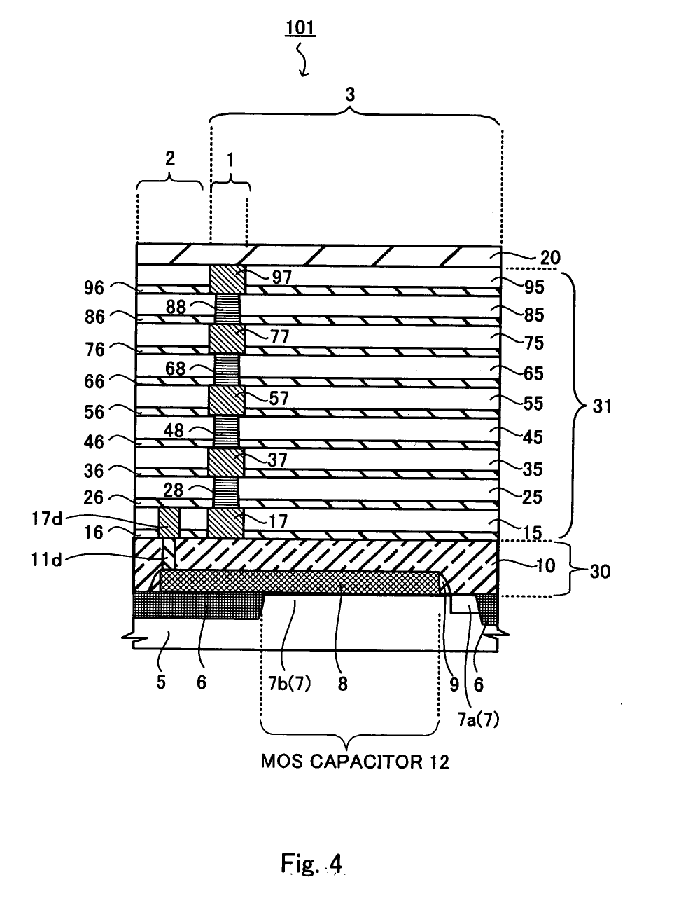

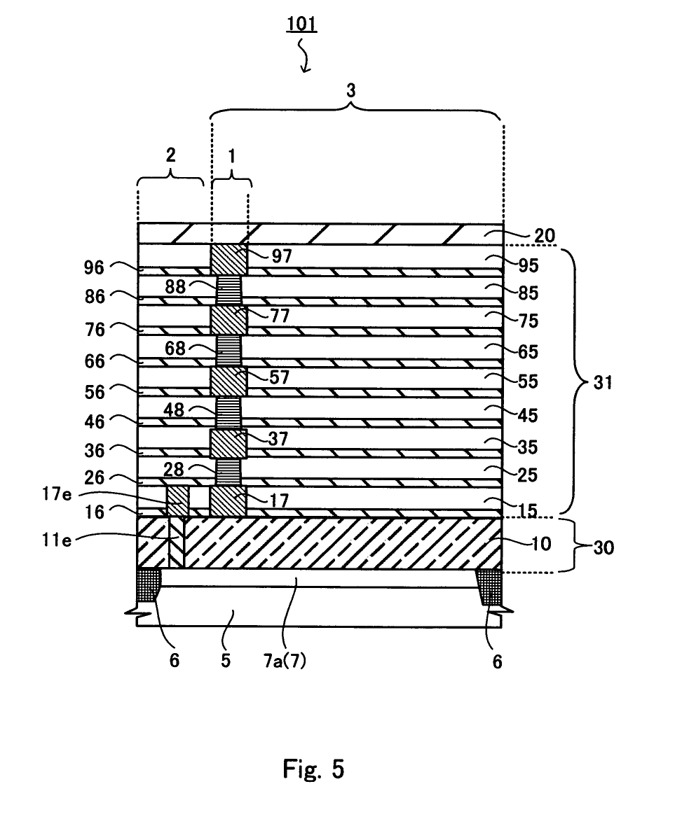

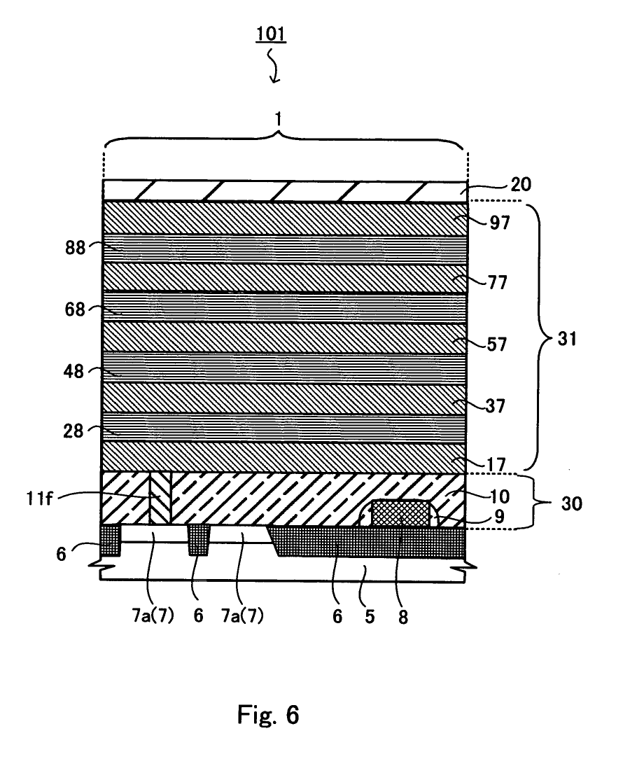

FIG. 3 shows a partially-enlarged schematic plan view around the frame region 3 shown by dotted lines A1 in FIG. 1B. FIG. 4 is a cross sectional view taken along the line IV-IV of FIG. 3, FIG. 5 shows a cross sectional view taken along the line V-V of FIG. 3, and FIG. 6 is a cross sectional view taken along the line VI-VI of FIG. 3.

As shown in FIG. 3, the N-type diffusion region 7a, the gate part 8, the three contacts 11d, 11e, and 11f, and the MOS-type capacitor (hereinafter referred to as “MOS capacitor”) 12 and the like are provided near the frame region 3 including the seal ring 1. The semiconductor substrate 5, the element protecting film 10, the first interlayer insulating film 15 to the ninth interlayer insulating film 95, the passivation protecting film 20, the wiring layer, and the etching stopper layer or the like are not shown in FIG. 3 for the sake of clarity. The components in FIG. 3 are shown by using the texture same to that in FIG. 1B for describing the position where the seal ring 1 is formed.

In the first exemplary embodiment, the MOS capacitor 12, which is the semiconductor element, is formed in a region that is both outside of the seal ring 1, in the frame region 3, as well as partially inside the inner region 2 (see FIGS. 3 and 4). The MOS capacitor 12 forms an anode electrode by the gate electrode in the gate part 8 and forms a cathode electrode by the inversion layer forming region 7b of the Si substrate below the gate electrode. The inversion layer forming region 7b below the gate electrode is in the low resistance as the inversion layer is formed by applying the voltage to the gate electrode; therefore the inversion layer forming region 7b functions as the cathode electrode. The capacitor insulating film is formed between the semiconductor substrate 5 and the gate electrode in the gate electrode part 8. The side walls 9 are formed in the both sides of the gate part 8.

The MOS capacitor 12 is formed so as to be electrically connected to the inner region 2. More specifically, the gate part 8 is extended to the inner region 2 in the anode side of the MOS capacitor 12. The gate electrode formed in the gate part 8 formed in the inner region 2 is electrically connected to the first wiring layer 17d through the contact 11d formed in the element protecting film 10 (see FIGS. 3 and 4) and is further connected to a VDD terminal. Further, the N-type diffusion region 7a on the semiconductor substrate 5 is extended to the inner region 2 in the cathode side of the MOS capacitor 12 as shown in FIGS. 3 and 5. Then the N-type diffusion region 7a on the semiconductor substrate 5 formed in the inner region 2 is electrically connected to the first wiring layer 17e through the contact 11e formed in the element protecting film 10 and is further connected to a GND terminal.

The MOS capacitor 12 is formed by the active region 7 of the semiconductor substrate 5 and the element protecting film 10 formed in the upper layer of the semiconductor substrate 5, as is the same as the MOS transistor 13 stated above.

The MOS capacitor 12 formed in the frame region 3 is electrically connected to the semiconductor element or the like formed in the inner region 2 by the above configuration. A conductive layer formed in the semiconductor substrate 5 or the element protecting film 10 is employed as the wiring line directly connecting the inner region 2 and the frame region 3. The wiring line is preferably a Cu-based wiring line, an Al-based wiring line, and a silicide wiring line such as NiSi, PtSi in addition to a diffusion layer formed in the semiconductor substrate 5 or the gate electrode stated above. The frame region 3 may be electrically connected to the inner region 2 by the conductive layer formed in the semiconductor substrate 5 or the element protecting film 10, and then the semiconductor element formed in the inner region 2 is directly connected to the frame region 3 through the conductive layer. Otherwise, as described above, the frame region 3 may be connected to the semiconductor element formed in the inner region 2 by way of the wiring layers or the via wiring layers or the like formed in the interlayer insulating films such as the first interlayer insulating film 15 or the like formed in the inner region 2. The inner region 2 is preferably connected to the Cu wiring line having lower electric resistance through the contact.

Although not specifically limited, the semiconductor element provided in the frame region 3 includes a diffusion layer resistor, a gate electrode resistor (poly resistor), a silicide resistor, a diode, or an MOS transistor in addition to the MOS capacitor, for example. As stated above, it is also possible to provide the semiconductor element for test as well in addition to the “semiconductor element which is operable as the internal circuit and has a high reliability”. The semiconductor element formed in the frame region 3 may be formed at a part of the sides of the semiconductor chip which is formed in a rectangular shape, or may be arranged in all the sides of the rectangular semiconductor chip.

Now, the structure of the seal ring 1 will be described. As shown in FIG. 1B, the seal ring 1 according to the first exemplary embodiment is provided in the frame body shape along with the outer periphery of the semiconductor chip 101 so as to surround the inner region 2. In the first exemplary embodiment, the seal ring 1 formed on the semiconductor substrate 5 comprises a gate electrode part 8, an element protecting film 10, a contact provided in the element protecting film 10, a wiring layer, a via wiring layer, and a passivation protecting film 20 and so on.

The seal ring 1 includes a frame body area where the conductive layers are superimposed in the film-thickness direction in the frame body shape so as to surround the inner region 2, and a thinning area where the conductive layers are intermittently formed. In the first exemplary embodiment, the area of the first interlayer insulating film 15 to the ninth interlayer insulating film 95 corresponds to a frame body area 31, and the element protecting film 10 corresponds to a thinning area 30 (see FIGS. 4 to 6). In other words, the semiconductor chip 101 according to the first exemplary embodiment includes the thinning area 30 formed in the upper layer of the semiconductor substrate 5 and the frame body area 31 formed in the upper layer of the thinning area 30, and then the frame body area 31 is covered with the passivation protecting film 20. Note that the thinning area 30 is not limited to one layer but can be a plurality of layers. The number of layers of the interlayer insulating film of the frame body area 31 is not specifically limited. The layer other than the above layers may also be included without departing from the scope of the present invention.

FIG. 6 is a cross sectional view of the seal ring 1. As stated above, in the seal ring 1 in the frame body area 31, the conductive layers are superimposed in the film-thickness direction in the frame body shape along with the outer periphery of the semiconductor chip 101 as described above. More specifically, as shown in FIG. 6, the wiring layers and the via wiring layers are alternately stacked. More specifically, the first wiring layer 17, the first via wiring layer 28, the second wiring layer 37, the second via wiring layer 48, the third wiring layer 57, the third via wiring layer 68, the fourth wiring layer 77, the fourth via wiring layer 88, and the fifth wiring layer 97 are stacked in this order. The passivation protecting film 20 is provided in the upper layer of the fifth wiring layer 97.

By forming the seal ring 1 of the frame body area 31 as described above, water and the like having penetrated into the low-dielectric-constant film making up the main portion of the interlayer insulating film in dicing is blocked from penetrating further deeply inward by the presence of the seal ring 1. Further, in the first exemplary embodiment, it is possible to effectively prevent water from being penetrated in the inner direction by employing the barrier metal as the seal ring 1 as described above. That is, besides general use as a barrier to prevent copper from being diffused to surroundings from the copper wiring line buried in the interlayer insulating film, the barrier metal layer can also be used so that it may act as a barrier against water and the like having penetrated from the surroundings as described above.

On the other hand, as shown in FIG. 6, the conductive layers penetrating the element protecting film 10 are intermittently provided in the seal ring 1 of the thinning area 30. More specifically, the contact 11f penetrating from the surface of the element protecting film 10 to the semiconductor substrate 5 is formed in the example shown in FIG. 6. Further, the gate part 8 is provided in the thinning area 30 (see FIGS. 4 to 6).

The seal ring 1 of the thinning area 30 is formed as above so that the gate electrode of the MOS capacitor 12 formed in the frame region 3 can be electrically connected to the inner region 2. In other words, the wiring line electrically connecting the frame region 3 and the inner region 2 can be longitudinally traversed in the thinning area 30 by intermittently providing the conductive layers instead of providing them in the frame body shape as in the frame body area 31.

The element protecting film 10 forming the thinning area 30 is formed of a film tougher than the low-dielectric-constant film and having high reliability. For example, a single layer or stacked layers selected from SiO, SiC, SiCN, SiON, and SiN is employed. The element protecting film 10 is formed by such the film so that reliability of the wiring line is not reduced due to the penetration of water or the like in dicing. The semiconductor element forming region can be extended to the frame region 3 not only to the inner region 2 by employing the thinning structure.

In the first exemplary embodiment, the conductive layer is arranged in the thinning area 30 of the seal ring 1 so that it is possible to prevent destruction of the semiconductor substrate 5. If the seal ring is exposed to plasma in a process of manufacturing the semiconductor device such as etching, CVD, and the like, ions having positive charge hit the semiconductor substrate 5, so that such a phenomenon occurs that the seal ring 1 is deprived of its inner electrons by the ions to thereby charge the wiring layers positively. In this case, if the seal ring 1 is in an electrically floating state, it continues to accumulate charge in it until it is discharged, whereupon the substrate 5 is destroyed. In such a case, according to the first exemplary embodiment, the conductive layer in the frame body area 31 is connected via the contact 11f to the N-type diffusion region 7a formed on the semiconductor substrate 5, so that its charge can be released through the semiconductor substrate 5, thereby preventing destruction of the semiconductor substrate 5.

Further, the wiring line electrically connecting the inner region 2 and the frame region 3 is arranged in the region where the conductive layers are thinned out. In other words, the Cu wiring lines in the interlayer insulating films formed in the frame body area 31 are not employed for connecting the semiconductor element of the frame region 3 and the inner region 2, but instead the gate electrode or the diffusion layer formed in the semiconductor substrate 5 and the element protecting film 10 formed in the thinning area 30 which does not reduce the reliability of the wiring line due to the penetration of the water are employed. Therefore, the reliability is not the problem. Further, the MOS capacitor which is the semiconductor element formed in the frame region 3 is formed by the inversion layer forming region of the Si substrate, the gate insulation film, and the gate electrode, and is formed of the layer not including the low-dielectric-constant film; therefore the reliability is not reduced also in the semiconductor element itself due to the penetration of water or the like in dicing.

As described above, according to the first exemplary embodiment, the semiconductor element capable of operating as a chip internal circuit can be arranged in the frame region 3 while realizing high reliability. In summary, according to the exemplary embodiment, the frame region 3 can be employed as the region where the semiconductor element operating as the internal circuit is provided, whereby high performance of the LSI can be realized and characteristics of the LSI can be improved without increasing the size of the semiconductor device. Otherwise, the semiconductor device can be made smaller while having the same function. Further, it is possible to reduce the cost because of the decreasing of the chip size.

If the exemplary embodiment is applied to a product of 6 mm*8 mm of 65 nm process, for example, the area of around 0.64 mm² can be newly obtained when the frame region 3 is employed as the region where the semiconductor element can be arranged. Further, when a decoupling capacitor (MOS capacitor) is arranged in the frame region 3, the mounting volume can be increased by about 19%. By increasing the mounting volume of the decoupling capacitor, the power supply noise can be reduced to improve the propagation delay of signals. As a result, the LSI operating in the higher speed (clock) can be manufactured.

### Second Exemplary Embodiment

Now, another example of a semiconductor chip which is different from the first exemplary embodiment will be described. Hereinafter, the same components as those of the first exemplary embodiment are denoted by the same reference symbols, and the description thereof will be omitted as appropriate.

The semiconductor chip according to the second exemplary embodiment has the basic structure same to that of the first exemplary embodiment except the following point. In the first exemplary embodiment, single seal ring 1 is arranged to surround the outer periphery of the semiconductor chip 101; in the second exemplary embodiment, triple seal rings 1a are arranged. Further, in the first exemplary embodiment, the MOS capacitor 12 is arranged in outer region than the seal ring 1 of the frame region 3; in the second exemplary embodiment, the MOS capacitor 12a is arranged from the frame region 3 including the region immediately below the seal ring to the inner region 2.

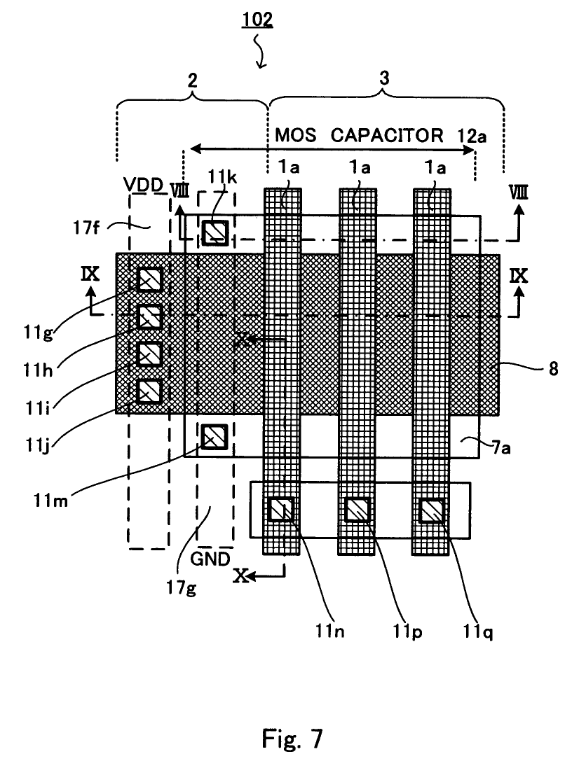

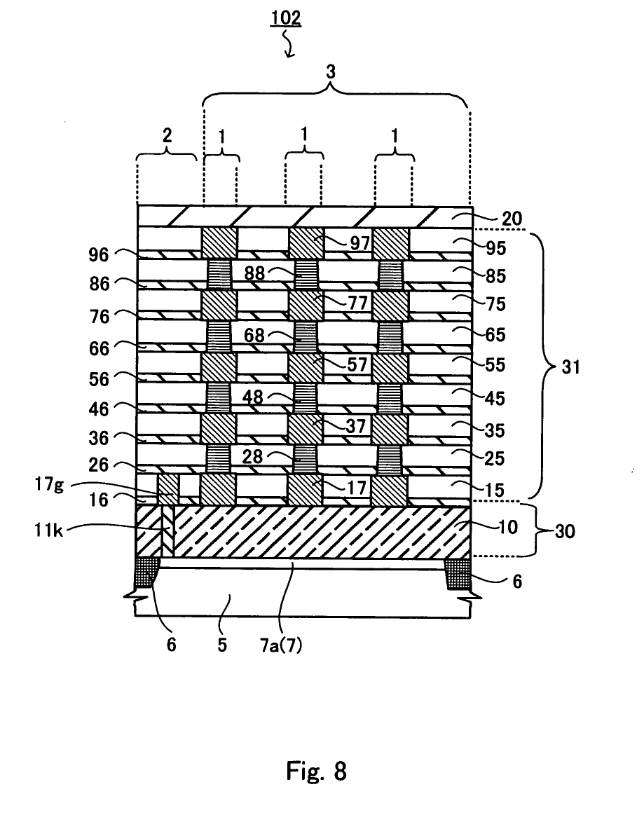

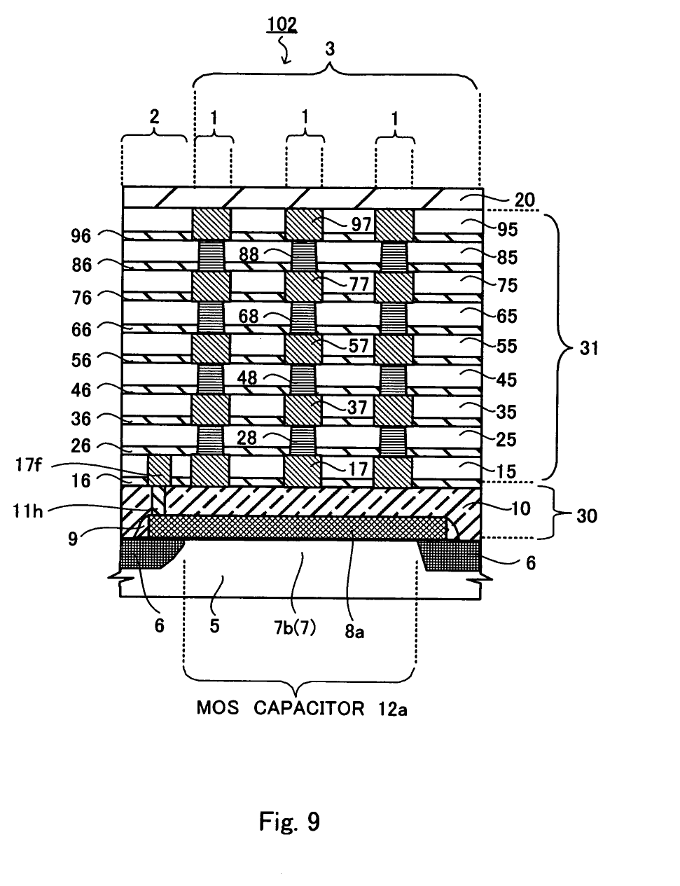

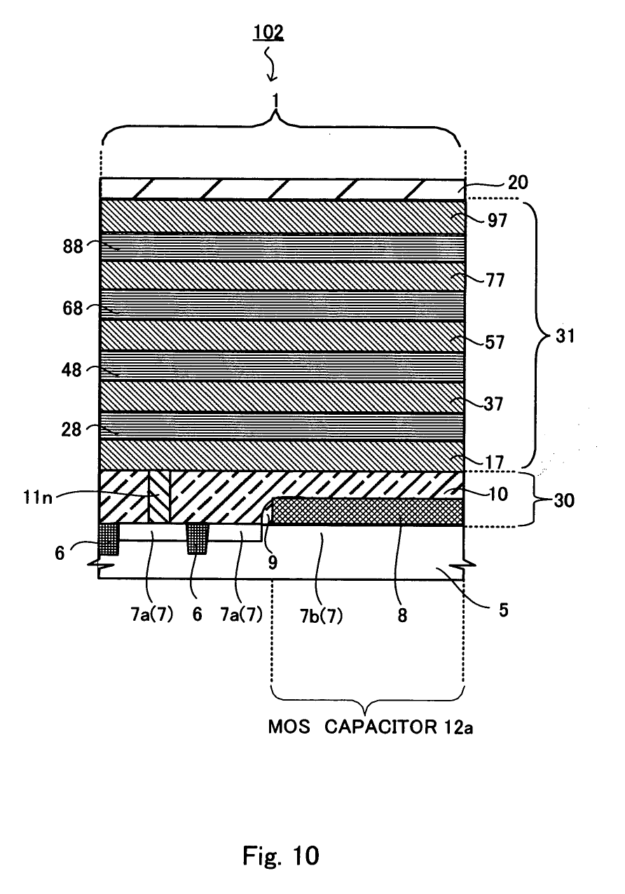

FIG. 7 shows a partially-enlarged schematic plan view around the frame region 3 of a semiconductor chip 102 according to the second exemplary embodiment. FIG. 8 is a cross sectional view taken along the line VIII-VIII of FIG. 7, and FIG. 9 is a cross sectional view taken along the line IX-IX of FIG. 7. FIG. 10 is a cross sectional view taken along the line X-X of FIG. 7.

As shown in FIG. 7, the semiconductor chip 102 according to the second exemplary embodiment includes three seal rings 1a, a gate part 8a, nine contacts 11 (11g, 11h, 11i, 11j, 11k, 11m, 11n, 11p, and 11q), and an MOS capacitor 12a and so on. In the drawing, the semiconductor substrate 5, the element protecting film 10, the first interlayer insulating film 15 to the ninth interlayer insulating film 95, the passivation protecting film 20, the wiring layer, and the etching stopper layer and so on are not shown for the sake of simplicity. Further, in order to describe the position where the seal ring 1 is formed, the components in FIG. 7 are shown by using the texture same to that in FIG. 3.

In the second exemplary embodiment, the MOS capacitor 12a which is the semiconductor element is provided from the frame region 3 to the inner region 2 (see FIGS. 7 and 9). More specifically, the gate part 8a is formed from the frame region 3 to the inner region 2 in the anode side of the MOS capacitor 12a. Then the gate electrode formed in the gate part 8a in the inner region 2 is electrically connected to the first wiring layer 17f through the contact 11h formed in the element protecting film 10 (see FIG. 9). The inversion layer forming region 7b of the semiconductor substrate 5 is formed from the frame region 3 to the inner region 2 in the cathode side of the MOS capacitor 12a as shown in FIG. 9. Further, as shown in FIGS. 7 and 8, the N-type diffusion region 7a is formed from the inner region 2 to longitudinally traverse the frame region 3. Then the N-type diffusion region 7a formed in the semiconductor substrate 5 in the inner region 2 is electrically connected to the first wiring layer 17g through the contact 11k formed in the element protecting film 10, and is further connected to the GND terminal.

In the second exemplary embodiment, the triple seal rings 1a are arranged, whereby the penetration of the water or the like inside the semiconductor chip due to the chipping or the like in dicing can be effectively suppressed. As a result, it is possible to provide the semiconductor chip having a higher quality and high reliability, and the semiconductor device having the semiconductor chip mounted thereon. Even when the triple seal rings 1a are provided, the semiconductor element can be provided which is operable as a chip internal circuit and realizes the high reliability in the region immediately below the seal ring 1a and the region segmented outside the seal ring 1a. Accordingly, it is possible to obtain the above effect without increasing the size of the semiconductor chip.

In the first and second exemplary embodiments, the layer formed of the element protecting film 10 is the thinning area 30, and the first interlayer insulating film 15 to the ninth interlayer insulating film 95 are the frame body area 31. However, the structure is merely one example and is not limited to this case. For example, the first interlayer insulating film 15 and the element protecting film 10 where the semiconductor element is formed may be the thinning area 30, and the second interlayer insulating film 25 to the ninth interlayer insulating film 95 may be the frame body area 31. In this case, the first interlayer insulating film 15 is not the low-dielectric-constant film but should be the film which is not damaged by the water or the like and having a high reliability. Further, the interlayer insulating films need not have the same structure but can be changed as appropriate.

Although the layer of forming the semiconductor element formed on the semiconductor substrate 5 is formed by one layer of the element protecting film 10 in the above exemplary embodiment, the aspect is not limited to this case but the semiconductor element may be formed in a plurality of layers formed on the semiconductor substrate 5. In this case, these layers can be the thinning area 30; alternatively only one layer can be the thinning area 30 and the inner region 2 and the semiconductor element formed in the frame region 3 may be electrically connected by the layer.

In the first exemplary embodiment, the single seal ring is formed; in the second exemplary embodiment, the triple seal rings are formed. However, the aspect is not limited to this case, but can be selected as appropriate according to the characteristics of the material employed as the interlayer insulating film or the moisture resistance that is required or the like. Further, although the example of providing the etching stopper film is described in this exemplary embodiment, the process can be omitted as appropriate. Furthermore, the first and second exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor chip, comprising:
a semiconductor substrate;
a multi-layer wiring structure on the semiconductor substrate, including a seal ring structure on the semiconductor substrate; and
a semiconductor element arranged in an inner region of said semiconductor chip and in a frame region of said semiconductor chip,
wherein the semiconductor element comprises a chip internal circuit element, the inner region is enclosed by the seal ling structure, and the seal ring structure separates the frame region as being outside of the inner region.

2. The semiconductor chip according to claim 1, wherein the semiconductor element arranged in the frame region comprises at least one of a metal-oxide semiconductor transistor, a metal-oxide semiconductor capacitor, a diffusion layer resistor, a gate electrode resistor, a silicide resistor, and a diode.

3. The semiconductor chip according to claim 1, wherein the semiconductor element arranged in the frame region is covered by at least one of an element protecting film of an upper layer of the semiconductor substrate and the semiconductor substrate, a main layer of interlayer insulating films comprising the multi-layer wiring structure formed on an upper layer of the element protecting film comprises a different material from the element protecting film, and the main layer of the interlayer insulating films comprises a low-dielectric-constant film.

4. The semiconductor chip according to claim 2, wherein the semiconductor element arranged in the frame region is covered by at least one of an element protecting film of an upper layer of the semiconductor substrate and the semiconductor substrate, a main layer of interlayer insulating films comprises the multi-layer wiring structure formed on an upper layer of the element protecting film is comprised of a different material from the element protecting film, and the main layer of the interlayer insulating films comprises low-dielectric-constant film.

5. The semiconductor chip according to claim 3, wherein the element protecting film comprises one of a single film and a stacked film made from any one of SiO, SiC, SiN, SICN, SiON, and SiN.

6. The semiconductor chip according to claim 3, wherein the seal ring structure includes a frame body area and a thinning area, the interlayer insulating film formed by the low-dielectric-constant film is formed in the frame body area, the element protecting film is formed in the thinning area, a conductive layer is formed around the inner region as a frame body and is formed superimposed in a film thickness direction in the frame body area, and the conductive film is formed intermittently in the thinning area.

7. The semiconductor chip according to claim 5, wherein the seal ring structure includes a frame body area and a thinning area, the interlayer insulating film formed by the low-dielectric-constant film is formed in the frame body area, the element protecting film is formed in the thinning area, a conductive layer is formed around the inner region as a frame body and is formed superimposed in a film thickness direction in the frame body area, and the conductive film is formed intermittently in the thinning area.

8. The semiconductor chip according to claim 6, wherein at least a part of a conductive film in the frame body area and the semiconductor substrate are electrically connected.

9. The semiconductor chip according to claim 3, wherein a wiring for connecting the semiconductor element formed in the frame region and the inner region comprises a wiring formed lower than the low-dielectric-constant film.

10. The semiconductor chip according to claim 5, wherein a wiring for connecting the semiconductor element formed in the frame region and the inner region comprises a wiring formed lower than the low-dielectric-constant film.

11. The semiconductor chip according to claim 6, wherein a wiring for connecting the semiconductor element formed in the frame region and the inner region comprises a wiring formed lower than the low-dielectric-constant film.

12. The semiconductor chip according to claim 8, wherein a wiring for connecting the semiconductor element formed in the frame region and the inner region comprises a wiring formed lower than the low-dielectric-constant film.

13. The semiconductor chip according to claim 9, wherein the wiring comprises at least one of a diffusion layer, a polycrystalline semiconductor layer, an Aluminum-based wiring, a cupper-based wiring and a silicide wiring.

14. The semiconductor chip according to claim 1, wherein the seal ring structure comprises one seal ring structure of a plurality of the seal ring structures, each seal ring structure being formed along an outer periphery of the semiconductor substrate.

15. The semiconductor chip according to claim 2, wherein the seal ring structure comprises one seal ring structure of a plurality of the seal ring structures, each seal ring structure being formed along an outer periphery of the semiconductor substrate.

16. The semiconductor chip according to claim 1, wherein the semiconductor element comprises one of a plurality of semiconductor elements, wherein a semiconductor element of the plurality of semiconductor elements is respectively arranged at each side of at least two sides configuring the frame region.

17. The semiconductor chip according to claim 2, wherein the semiconductor element comprises one of a plurality of semiconductor elements, wherein a semiconductor element of the plurality of semiconductor elements is respectively arranged at each side of at least two sides configuring the frame region.

18. A semiconductor device comprising:
a semiconductor substrate; and
a semiconductor chip including a multi-layer wiring structure and a seal ring structure on the semiconductor substrate,
wherein the semiconductor chip comprises a semiconductor element arranged in an inner region of the semiconductor chip a frame region of the semiconductor chip, the semiconductor element comprising a chip internal circuit component, the inner region being enclosed to be inside of the seal ring structure, and the frame region is separated as outside of the inner region by the seal ring structure.

19. The semiconductor device according to claim 18, wherein the semiconductor element arranged in the frame region comprises at least one of a metal-oxide semiconductor transistor, a metal-oxide semiconductor capacitor, a diffusion layer resistor, a gate electrode resistor, a silicide resistor, and a diode.

20. The semiconductor device according to claim 18, wherein the semiconductor element arranged in the frame region is covered by at least one of an element protecting film of an upper layer of the semiconductor substrate and the semiconductor substrate, a main layer of interlayer insulating films comprising the multi-layer wiring structure formed on an upper layer of the element protecting film is comprised of a different material from the element protecting film, and the main layer of the interlayer insulating films comprises a low-dielectric-constant film.

21. A method of fabricating a semiconductor chip, said method comprising:
forming a semiconductor element on a substrate; and
forming a multi-layer wiring structure on the substrate, including a seal ring structure,
the seal ring structure separates the chip into an inner region enclosed by the seal ring structure and a frame region being outside the seal ring structure, and
the semiconductor element comprises a chip internal circuit component and is located partially in the inner region and partially in the frame region.
